(19) United States
(12) Patent Application Publication
(10) Pub. No.: US 2026/0060135 A1
(43) Pub. Date: Feb. 26, 2026

(54) SEMICONDUCTOR DEVICE

(71) Applicant: FUJI ELECTRIC CO., LTD., Kawasaki-shi (JP)

(72) Inventors: Akira ISO, Kai-city (JP); Taichi ITOH, Matsumoto-city (JP)

(73) Assignee: FUJI ELECTRIC CO., LTD., Kawasaki-shi (JP)

(21) Appl. No.: 19/253,135

(22) Filed: Jun. 27, 2025

(30) Foreign Application Priority Data
Aug. 20, 2024 (JP) 2024-139186

(51) Int. Cl. H01L 23/24; H01L 23/00; H01L 23/053; H01L 23/29; H01L 23/31; H01L 23/367; H01L 23/498

(52) U.S. Cl. CPC H01L 23/24; H01L 23/053; H01L 23/296; H01L 23/3121; H01L 23/3675; H01L 23/49811; H01L 24/32; H01L 24/48; H01L 24/73; H01L 2224/32225; H01L 2224/48237; H01L 2224/73265

(57) ABSTRACT

A semiconductor device includes a substrate having a semiconductor chip mounted thereon, a heat dissipation plate having a front surface on which the substrate is disposed, a case including a side wall disposed on the front surface of the heat dissipation plate so as to surround a housing space accommodating the substrate therein together with the heat dissipation plate and a lid disposed on the side wall to cover the housing space, and a sealing member filling the housing space to seal the substrate. The lid has a through hole and a projection (or a groove) provided on the inner surface of the lid, configured to surround the through hole so as not to contact the sealing member such that the projection forms a plurality of circumferential patterns around the through hole in plan view.

### CROSS-REFERENCE TO RELATED APPLICATION

This application is based upon and claims the benefit of priority of the prior Japanese Patent Application No. 2024-139186, filed on Aug. 20, 2024, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device has, on the inner surface of the lid, projections that allow a sealing member to contact the projections and flow up the surfaces of the projections, in order to prevent the sealing member from leaking from a terminal hole provided in the lid or a gap between the case and the lid (for example, refer to Japanese Laid-open Patent Publication No. 2023-042658 and Japanese Laid-open Patent Publication No. 2003-297979). Another semiconductor device has a projection for preventing leakage of a sealing member on the inner wall of the case, and yet another semiconductor device has projections for holding terminals that are provided on the inner wall of the case so that the upper surface of each projection is separated from the lower surface of the lid to prevent a sealing member from creeping up to the lid (for example, refer to Japanese Laid-open Patent Publication No. 2017-059715 and Japanese Laid-open Patent Publication No. 2011-243798).

With respect to a semiconductor device having a through hole in the lid of the case, leakage of a sealing member to the outside via the through hole is conventionally unavoidable.

### SUMMARY OF THE INVENTION

According to an aspect of the present disclosure, there is provided a semiconductor device, including: a semiconductor chip; a substrate having the semiconductor chip mounted thereon; a heat dissipation plate having a front surface on which the substrate is disposed; a case having a side wall and a lid, the side wall being disposed on the front surface of the heat dissipation plate so as to surround a housing space together with the heat dissipation plate, the housing space accommodating the substrate therein, the lid being disposed on the side wall to cover the housing space; and a sealing member filling the housing space to seal the substrate, wherein the lid includes a through hole, and at least one projection or groove provided on an inner surface of the lid, configured to surround the through hole so as not to contact the sealing member such that the at least one projection or groove forms a plurality of circumferential patterns around the through hole in a plan view of the semiconductor device.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a side sectional view of a semiconductor device according to a first embodiment;

FIG. 2 is a top view illustrating part of the semiconductor device according to the first embodiment;

FIG. 3 is an enlarged view of projections;

FIG. 4 is a diagram for describing the creeping of a sealing member in a semiconductor device according to a reference example;

FIG. 5 is a diagram for describing the creeping of a sealing member in the semiconductor device according to the first embodiment;

FIG. 6 illustrates an example the of arrangement positions of projections with respect to creeping directions of a liquid material contained in the sealing member in the semiconductor device according to the first embodiment;

FIG. 7 is a perspective view illustrating a state in which the liquid material spreads in a region where the projections are provided;

FIG. 8 is a side sectional view of a semiconductor device according to a second embodiment;

FIG. 9 is a top view illustrating part of the semiconductor device according to the second embodiment;

FIG. 10 is an enlarged view of grooves;

FIG. 11 is a diagram for describing the creeping of a sealing member in the semiconductor device according to the second embodiment;

FIG. 12 is a side sectional view of a semiconductor device according to a first modification;

FIG. 13 is a top view illustrating part of a semiconductor device according to a second modification;

FIG. 14 is a side sectional view of a semiconductor device according to a third modification; and

FIG. 15 is a top view illustrating part of the semiconductor device according to the third modification.

### DETAILED DESCRIPTION OF THE INVENTION

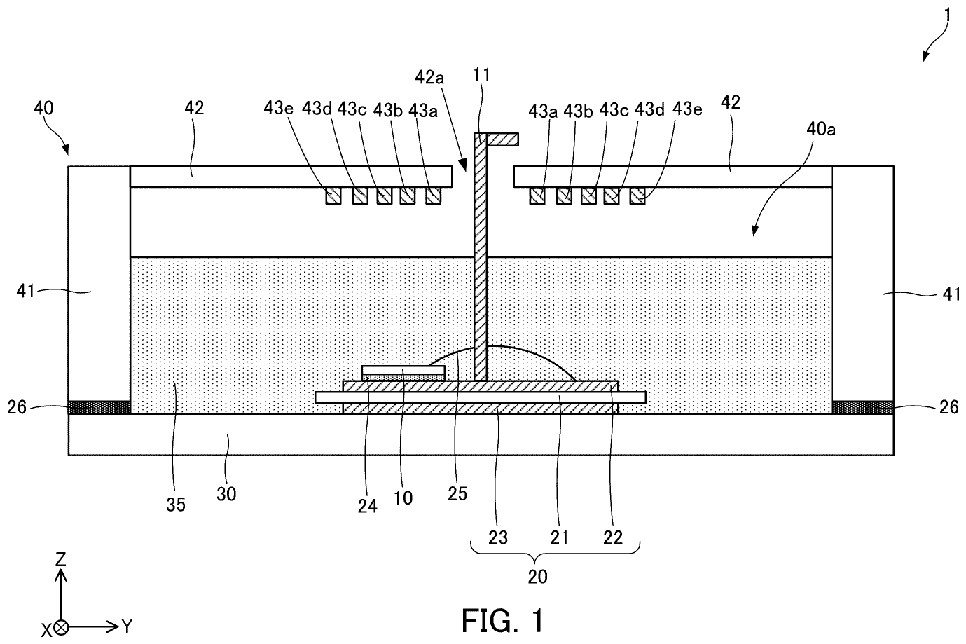

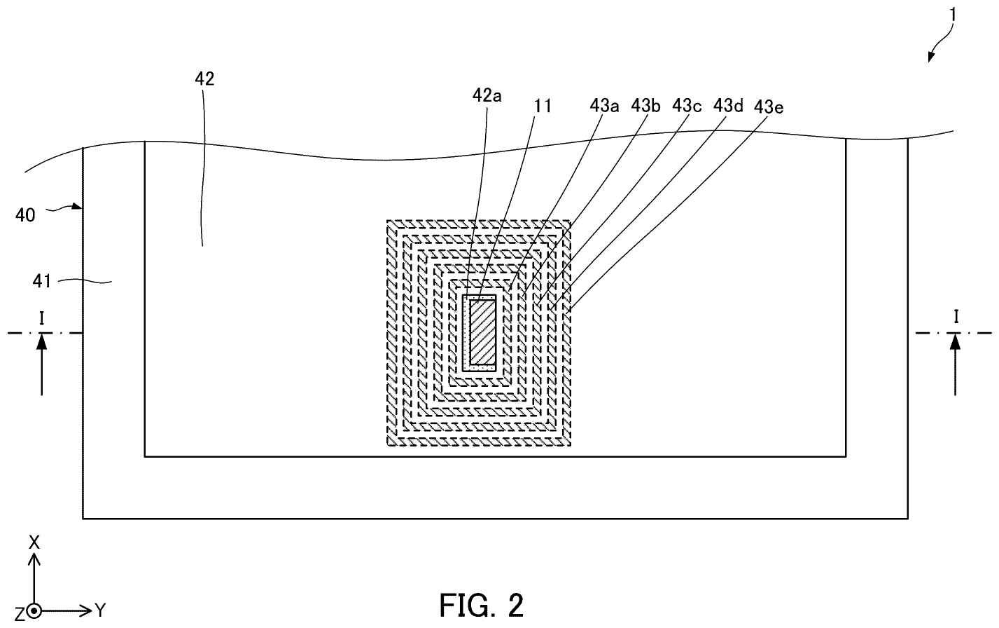

Hereinafter, embodiments will be described with reference to the accompanying drawings. In the following description, the terms “front surface” and “upper surface” refer to the X-Y plane facing upward (the +Z direction) in a semiconductor device 1 illustrated in FIGS. 1 and 2. Similarly, the term “up” refers to the upward direction (the +Z direction) in the semiconductor device 1 illustrated in FIGS. 1 and 2. The terms “rear surface” and “lower surface” refer to the X-Y plane facing downward (the −Z direction) in the semiconductor device 1 illustrated in FIGS. 1 and 2. Similarly, the term “down” refers to the downward direction (the −Z direction) in the semiconductor device 1 illustrated in FIGS. 1 and 2. The same directionality applies to the other drawings as appropriate. The terms “front surface,” “upper surface,” “up,” “rear surface,” “lower surface,” and “down” are used for convenience to describe relative positional relationships, and do not limit the technical concept of the embodiments. For example, the terms “up” and “down” are not always related to the vertical directions to the ground. That is, the “up” and “down” directions are not limited to those related to the gravity direction. In addition, in the following description, the term “main component” refers to a component contained at 80% or more by volume.

### First Embodiment

A semiconductor device according to a first embodiment will be described with reference to FIGS. 1 and 2.

FIG. 1 is a side sectional view of the semiconductor device according to the first embodiment. FIG. 2 is a top view illustrating part of the semiconductor device according to the first embodiment. The sectional view of FIG. 1 is a view taken along the dash-dotted line I-I in FIG. 2. In FIG. 2, the positions of projections 43a to 43e formed on the inner surface of a lid 42 are indicated by broken lines.

As illustrated in FIG. 1, the semiconductor device 1 includes a substrate 20 on which a semiconductor chip 10 and an external connection terminal 11 are mounted, a heat dissipation plate 30 having a front surface on which the substrate 20 is disposed, a sealing member 35, and a case 40.

The semiconductor chip 10 is mechanically and electrically (directly) connected to the substrate 20 with a bonding wire 25. In the case where a plurality of semiconductor chips 10 are provided, bonding wires 25 may be used to electrically connect the plurality of semiconductor chips 10 to each other. The semiconductor chip 10 includes a power device element that is made of, for example, silicon, silicon carbide, or gallium nitride. The thickness of the semiconductor chip 10 is in the range of 40 μm to 250 μm, inclusive, for example. The power device element is a switching element or a diode element.

The switching element is, for example, an insulated gate bipolar transistor (IGBT) or a power metal-oxide-semiconductor field-effect transistor (MOSFET). Such a semiconductor chip 10 includes, for example, a drain electrode (or a collector electrode) as a main electrode on the rear surface thereof, and a gate electrode and a source electrode (or an emitter electrode) as a control electrode and a main electrode on the front surface thereof.

The diode element is, for example, a freewheeling diode (FWD) such as a Schottky barrier diode (SBD) or a P-intrinsic-N (PiN) diode. Such a semiconductor chip 10 includes a cathode electrode as a main electrode on the rear surface thereof and an anode electrode as a main electrode on the front surface thereof.

As the semiconductor chip 10, at least one of a switching element and a diode element is selected as needed. Then, the rear surface of the semiconductor chip 10 is directly bonded to the predetermined circuit pattern 22 of the substrate 20 by a bonding member 24. The bonding member 24 is solder or a sintered metal body. As the solder, lead-free solder is used. The lead-free solder contains, for example, an alloy containing at least two of tin, silver, copper, zinc, antimony, indium, and bismuth as a main component. Furthermore, the solder may contain an additive. The additive is, for example, nickel, germanium, cobalt, or silicon. The solder containing such an additive exhibits improved wettability, gloss, and bonding strength, which improves reliability. The metal used in the sintered metal body is, for example, silver or a silver alloy.

The semiconductor chip 10 may be a reverse-conducting (RC)-IGBT having both functions of an IGBT and an FWD.

The external connection terminal 11 is electrically connected to either the main electrode or the control electrode of the semiconductor chip 10. The inner end portion (lower side in the drawing) of the external connection terminal 11 is bonded to the substrate 20, and the outer end portion (upper side in the drawing) of the external connection terminal 11 extends outward from a through hole 42a, which is described later, provided in the lid 42 of the case 40. A plurality of external connection terminals 11 may be mounted on the substrate 20. When the semiconductor device 1 is an inverter device, for example, the following four external connection terminals may be provided: a first input terminal to which the positive terminal of a direct current (DC) power supply is connected, a second input terminal to which the negative terminal of the DC power supply is connected, a first output terminal, and a second output terminal.

The external connection terminal 11 has a columnar shape, a prismatic shape, or a plate shape. The external connection terminal 11 is made of a metal having excellent electrical conductivity. Such a metal is, for example, copper, aluminum, or an alloy containing at least one of these metals as its main component. The diameter of the external connection terminal 11 (the length of a diagonal line in the case of a prismatic shape) is in the range of 0.5 mm to 2.5 mm, inclusive. In the case where the external connection terminal 11 has a plate shape, the thickness is in the range of 0.5 mm to 2.5 mm, inclusive. The surface of the external connection terminal 11 may be plated. The plating material used here is, for example, nickel, a nickel-phosphorus alloy, or a nickel-boron alloy. The plated external connection terminal 11 has improved corrosion resistance. The inner end portion of the external connection terminal 11 is bonded to the circuit pattern 22 of the substrate 20 by a bonding member. The bonding member is solder or a sintered metal body. As the solder, lead-free solder is used. The lead-free solder contains, for example, an alloy containing at least two of tin, silver, copper, zinc, antimony, indium, and bismuth as a main component. Furthermore, the solder may contain an additive. The additive is, for example, nickel, germanium, cobalt, or silicon. The solder containing such an additive exhibits improved wettability, gloss, and bonding strength, which improves reliability. The metal used in the sintered metal body is, for example, silver or a silver alloy. The external connection terminal 11 may be bonded to the circuit pattern 22 by ultrasonic bonding.

The substrate 20 includes an insulating plate 21, the circuit pattern 22, and a metal plate 23. The insulating plate 21 and the metal plate 23 have a rectangular shape in plan view. Corner portions of the insulating plate 21 and the metal plate 23 may be chamfered. For example, the chamfering may be C-chamfering or R-chamfering. The size of the metal plate 23 is smaller than that of the insulating plate 21 in plan view, and the metal plate 23 is formed inside the insulating plate 21. The insulating plate 21 is made of a material having an insulating property and excellent thermal conductivity. The insulating plate 21 is made of ceramics or insulating resin. The ceramics is aluminum oxide, aluminum nitride, silicon nitride, or the like. The insulating resin is, for example, a paper phenol substrate, a paper epoxy substrate, a glass composite substrate, or a glass epoxy substrate. The thickness of the insulating plate 21 is in the range of 0.2 mm to 2.5 mm, inclusive.

The circuit pattern 22 is formed on the front surface of the insulating plate 21. The circuit pattern 22 is made of a metal having excellent electrical conductivity. Such a metal is, for example, copper, aluminum, or an alloy containing at least one of these metals as a main component. The thickness of the circuit pattern 22 is in the range of 0.1 mm to 2.0 mm, inclusive. The surface of the circuit pattern 22 may be plated. The plating material used here is, for example, nickel, a nickel-phosphorus alloy, or a nickel-boron alloy. The plated circuit pattern 22 has improved corrosion resistance. The circuit pattern 22 is formed on the front surface of the insulating plate 21 as follows, for example. A metal plate is formed on the front surface of the insulating plate 21, and is then processed by etching or another to obtain the circuit pattern 22 having a predetermined shape. Alternatively, the circuit pattern 22 cut out from a metal plate in advance may be pressure-bonded to the front surface of the insulating plate 21. The circuit pattern 22 is an example. The number of circuit patterns 22, as well as their shapes, sizes, and positions, may be selected as appropriate.

The metal plate 23 is formed on the rear surface of the insulating plate 21. The metal plate 23 has a rectangular shape. The area of the metal plate 23 in plan view is smaller than that of the insulating plate 21 and larger than that of the region where the circuit pattern 22 is formed. Corner portions of the metal plate 23 may be chamfered. For example, the chamfering may be C-chamfering or R-chamfering. The metal plate 23 is smaller in size than the insulating plate 21 and is formed on the entire surface of the insulating plate 21 except the edge portion thereof. The metal plate 23 is made of a metal having excellent thermal conductivity as its main component. The metal is, for example, copper, aluminum, or an alloy containing at least one of these metals. The thickness of the metal plate 23 is in the range of 0.1 mm to 2.5 mm, inclusive. The surface of the metal plate 23 may be plated. The plating material used here is, for example, nickel, a nickel-phosphorus alloy, or a nickel-boron alloy. The plated metal plate 23 has improved corrosion resistance. The metal plate 23 is formed on the rear surface of the insulating plate 21 as follows. A metal plate is formed on the rear surface of the insulating plate 21, and is processed by etching or another to obtain the metal plate 23. Alternatively, the metal plate 23 cut out from a metal plate in advance may be pressure-bonded to the front surface of the insulating plate 21. Corner portions of the metal plate 23 provided on the rear surface of the insulating plate 21 in this manner may be R-chamfered or C-chamfered.

As the substrate 20 having such a configuration, for example, a direct copper bonding (DCB) substrate, an active metal brazed (AMB) substrate, or a resin insulating substrate may be used. The substrate 20 may be attached to the front surface of the heat dissipation plate 30 via a bonding member such as solder. In addition to the semiconductor chip 10, other electronic components (for example, a thermistor, a current sensor, and others), a lead frame, and others may be disposed on the substrate 20. Heat generated by the semiconductor chip 10 is conducted to the heat dissipation plate 30 via the circuit pattern 22, the insulating plate 21, and the metal plate 23, and is then dissipated. The semiconductor device 1 may include a plurality of substrates 20.

The sealing member 35 fills the housing space 40a housing therein the substrate 20 to seal the substrate 20 and others. As illustrated in FIG. 1, the sealing member 35 fills the case 40 up to such a height that the sealing member 35 seals at least the semiconductor chip 10, the substrate 20, and the bonding wires 25.

In addition, the sealing member 35 fills the case 40 up to such a height that the sealing member 35 does not contact the inner surface (rear surface) of the lid 42. That is, there is a gap between the inner surface (rear surface) of the lid 42 and the top surface of the sealing member 35. This gap may be 5% or more and 100% or less, preferably 10% or more and 50% or less, of the filling height of the sealing member 35. If the gap is too small, the lid may be pushed up and damaged when the sealing member 35 thermally expands. If this gap is too large, on the other hand, there is a possibility that the semiconductor device 1 becomes thick and is not able to be placed in a predetermined space in electrical equipment. Another possibility is that the substrate 20, the semiconductor chip 10 mounted on the substrate 20, and the wires connecting the semiconductor chip 10 and the substrate 20 are not sufficiently sealed, with some portions remaining exposed, which reduces the insulating property.

The sealing member 35 is, for example, silicone gel. The main material of the silicone gel is a polymeric siloxane entangled in a chain structure. The silicone gel contains a liquid low-molecular-weight siloxane. The liquid low-molecular-weight siloxane is contained in the silicone gel in an amount of, for example, 20 wt % or more and 30 wt % or less. The liquid low-molecular-weight siloxane is not entangled in a chain structure, and fills the gaps of the polymeric siloxane. The liquid low-molecular-weight siloxane functions as a buffer against thermal stress due to temperature changes. Therefore, the liquid low-molecular-weight siloxane is able to maintain the insulating function against the temperature changes of the sealing member 35.

The sealing member 35 is not limited to silicone gel. As the sealing member 35, another material that is in a gel state when filling the housing space 40a may be used. The gel-like material may contain a liquid material (oil component) that seeps out of the sealing member 35 after curing as described later.

As illustrated in FIGS. 1 and 2, the case 40 includes side walls 41 and a lid 42. The side walls 41 are disposed on the front surface of the heat dissipation plate 30 so as to surround the housing space 40a housing therein the substrate 20 together with the heat dissipation plate 30. The heights of the side walls 41 may be sufficiently higher than the height of the stacked substrate 20 and semiconductor chip 10. In the example of FIG. 1, the side walls 41 are attached by an adhesive 26 along the outer peripheral portion of the front surface of the heat dissipation plate 30. The adhesive 26 is made from an organic adhesive as its main component. The organic adhesive has a heat-resistant temperature of about 100° C. to 200° C. Specifically, the adhesive is an epoxy-based, silicone-based, or acrylic-based adhesive. The adhesive may be in the form of a paste or a sheet.

The lid 42 is disposed on the side walls 41 to cover the housing space 40a. In the example of FIG. 1, the lid 42 is connected to the tops of the side walls 41 to cover the housing space 40a. In addition, a through hole 42a is formed in the lid 42 to penetrate through the lid 42 in the ±Z direction, and projections 43a to 43e are formed on the lid 42. In the example of FIGS. 1 and 2, the through hole 42a serves as a terminal hole through which the outer end portion of the external connection terminal 11 is inserted. In the case where the through hole 42a is used as such a terminal hole, the through hole 42a may be formed so as to allow the external connection terminal 11 to be inserted thereinto without contact. The shape of the through hole 42a may be a rectangular shape or a circular shape in plan view. In the example of FIG. 2, the through hole 42a has a rectangular shape. This corresponds to the cross-sectional shape of the external connection terminal 11.

In the case where the through hole 42a is used as the terminal hole, the through hole 42a is formed in the lid 42 at a position corresponding to the position of the external connection terminal 11 in plan view. The number of through holes 42a may correspond to the number of external connection terminals 11. The through hole 42a may be used for a purpose different from that of the terminal hole. For example, there may be a case where the substrate 20 and a wiring substrate to be disposed on the substrate 20 may be positioned inside the case 40. In this case, the substrate 20 has an opening for the positioning on the front surface thereof, and the wiring substrate has a through hole. Then, a rod-shaped positioning member is inserted into the opening of the front surface of the substrate 20, the through hole of the wiring substrate, and the through hole 42a of the lid 42 of the case 40 to perform the positioning. Further, the lid 42 may have a plurality of through holes 42a formed for different purposes.

The projections 43a to 43e surround the through hole 42a over a plurality of circumferences to form circumferential patterns in plan view as illustrated in FIG. 2, and are provided on the inner surface (rear surface) of the lid 42 so as not to contact the sealing member 35 as illustrated in FIG. 1. In the example of FIG. 2, the projections 43a to 43e are provided so as to surround the through hole 42a over the plurality of circumferences in a loop shape in plan view. More specifically, the projections 43a to 43e are provided in the same number as the plurality of circumferences along the long side direction of the rectangular heat dissipation plate 30, and are also provided in the same number as the plurality of circumferences along the short side direction of the heat dissipation plate 30. The outer shape of each of the projections 43a to 43e is rectangular in plan view.

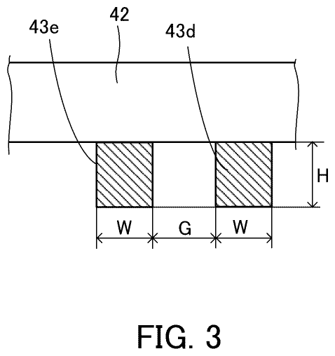

FIG. 3 is an enlarged view of projections. The enlarged view of FIG. 3 illustrates the projections 43d and 43e. The heights of the projections 43d and 43e are denoted as H, the widths thereof are denoted as W, and the interval between the projections 43d and 43e adjacent to each other in the inner peripheral direction or the outer peripheral direction is denoted as G. In the following description, with regard to the other projections 43a to 43c, their heights are denoted as H, their widths are denoted as W, and the intervals between projections adjacent to each other in the inner peripheral direction or the outer peripheral direction are denoted as G.

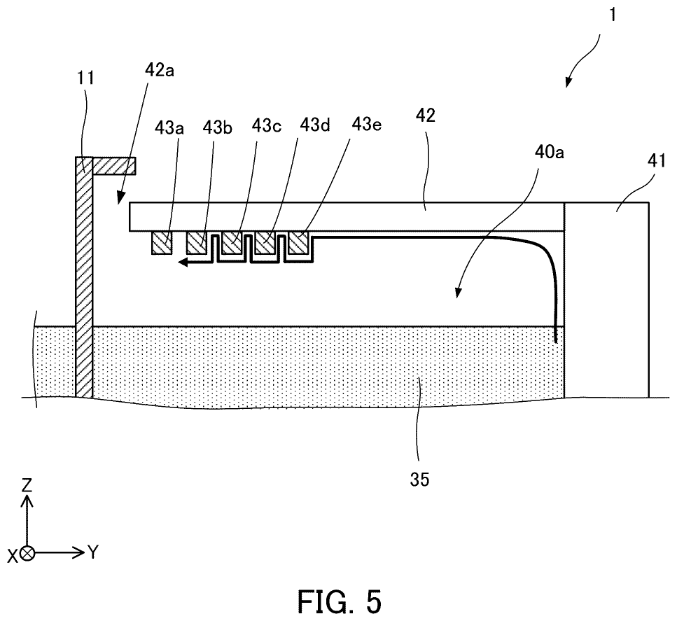

Incidentally, in order to maintain the strength of the case 40, the case 40 may have beams formed in a lattice pattern on the inner surface of the lid 42. In the case where a plurality of external connection terminals 11 are provided, the beams may be provided between the terminals to maintain the insulation distances therebetween. In such a case 40, the projections 43a to 43e do not need to have the function of maintaining the strength of the case 40 or the function of maintaining the insulation distances between terminals, like the beams do. In addition, if the sizes of the projections 43a to 43e are too large, there is a possibility that manufacturing of the beams is hindered. However, as will be described later (see FIGS. 5 to 7), the projections 43a to 43e need to act to prevent the liquid material contained in the sealing member 35 from reaching the through hole 42a.

In view of the above, the heights H of the projections 43a to 43e are preferably 2 mm or less, and the intervals G are preferably in the range of 0.5 mm to 1.5 mm, inclusive. The projections 43a to 43e do not need to have the same height H or the same width W. Further, the projections 43a to 43e do not need to have the same interval G therebetween. In the example of FIGS. 1 and 3, the projections 43a to 43e extend vertically from the inner surface of the lid 42 toward the housing space 40a, but are not limited to thereto. The projections 43a to 43e may be inclined within a range of about ±45° relative to the −Z direction from the inner surface of the lid 42.

In the example of FIG. 2, the projections 43a to 43e surround the through hole 42a over five circumferences in plan view, but are not limited to thereto. The lid 42 may be formed with projections that surround the through hole 42a over two to four circumferences or over six or more circumferences.

The case 40 having the projections 43a to 43e as described above is made of resin. The resin is made from a thermoplastic resin as a main component. The thermoplastic resin is, for example, a polyphenylene sulfide resin, a polybutylene terephthalate resin, a polybutylene succinate resin, a polyamide resin, or an acrylonitrile butadiene styrene resin. A filler may be added to such a resin. Examples of the filler include glass, silicon oxide, aluminum oxide, silicon nitride, and boron nitride. The case 40 is formed by filling a predetermined mold with such a resin, solidifying the resin, and removing the mold. The side walls 41 and the lid 42 may be formed by integral molding. Alternatively, the side walls 41 and the lid 42 may be separately molded. In this case, the lid 42 is bonded to the upper portions of the side walls 41 with an adhesive.

The lid 42 and the projections 43a to 43e may be formed by integral molding. Alternatively, the lid 42 and the projections 43a to 43e may be separately molded. In the case where the lid 42 and the projections 43a to 43e are separately molded, the projections 43a to 43e are attached to predetermined positions of the flat plate-shaped lid 42 by, for example, an adhesive. The lid 42 and the projections 43a to 43e may be made of different materials.

A cooling unit may be attached to the rear surface of the semiconductor device 1 (more specifically, the rear surface of the heat dissipation plate 30) via a bonding member. The bonding member is solder, a brazing material, or a sintered metal body. Alternatively, the bonding member may be a thermal interface material. The thermal interface material is, for example, an adhesive material such as an elastomer sheet, a room temperature vulcanization (RTV) rubber, a gel, or a phase change material. The use of the brazing material or the thermal interface material to attach the semiconductor device 1 to the cooling unit improves the heat dissipation of the semiconductor device 1.

The cooling unit is, for example, a cooling device that performs cooling using a heat sink or a refrigerant. As the heat sink, a plurality of fins may be directly attached to the rear surface of the heat dissipation plate 30. The heat sink is also made of a metal having excellent thermal conductivity as its main component, as with the heat dissipation plate 30. The metal is, for example, copper, aluminum, or an alloy containing at least one of these metals.

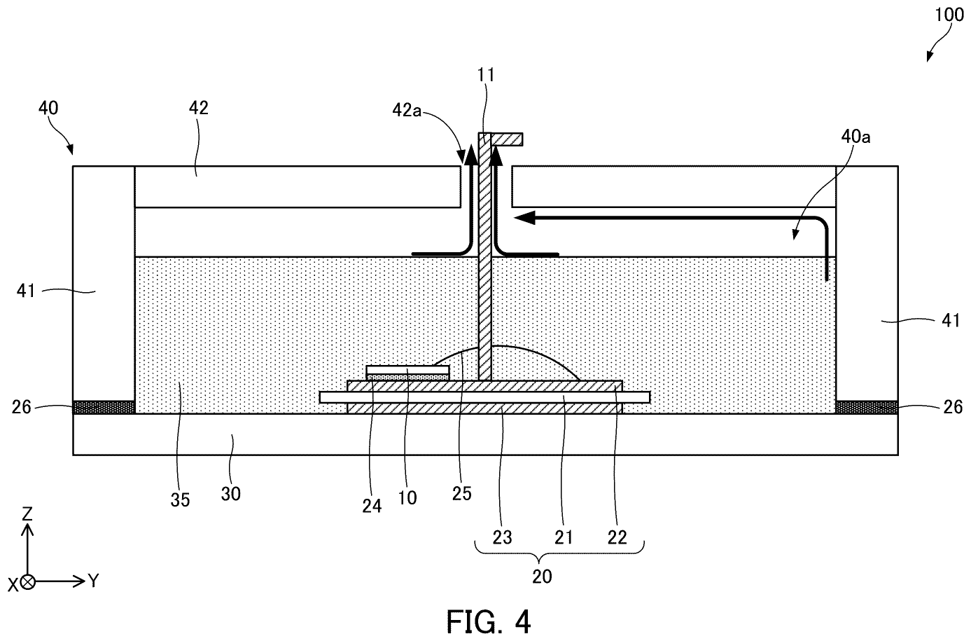

Next, a semiconductor device that does not include the projections 43a to 43e, as a reference example of the semiconductor device 1, and problems thereof will be described with reference to FIG. 4.

FIG. 4 is a diagram for describing the creeping of a sealing member in the semiconductor device according to the reference example. The semiconductor device 100 illustrated in FIG. 4 is obtained by removing the projections 43a to 43e from the semiconductor device 1. The remaining configuration of the semiconductor device 100 is the same as that of the semiconductor device 1.

As described above, the sealing member 35 of the semiconductor device 100 may contain a liquid material. For example, in the case where the sealing member 35 is silicone gel, the liquid material is liquid low-molecular-weight siloxane. Such a liquid material may seep out to the surface of the sealing member 35 as the semiconductor device 100 continues to be used after the sealing member 35 is cured. One of the causes is that the temperatures of the components in the housing space 40a repeatedly rise and fall due to repeated energization and interruption of the semiconductor chip 10, and the sealing member 35 thus repeatedly expands and contracts. When the mechanical pressure is applied to the sealing member 35 in this manner, the liquid material may seep out to the surface of the sealing member 35.

Due to capillary action, the seeped liquid material may creep up a component contacting the sealing member in the housing space 40a. For example, the liquid material creeps up the inner wall of a side wall 41 of the case 40 (in the +Z direction). The liquid material then reaches the through hole 42a from the side wall 41 of the case 40 along the rear surface of the lid 42, and seeps to the outside from the through hole 42a. For example, such seeping of the liquid material may be found when maintenance of the semiconductor device 100 is carried out or a failure occurs after 5 to 10 years have elapsed from the start of use of the semiconductor device 100. In addition, the liquid material may creep up the external connection terminal 11 (in the +Z direction) and seep to the outside from the through hole 42a.

The liquid material having seeped out of the semiconductor device 100 through the through hole 42a may contaminate the surroundings and may contaminate a handler when the handler handles the semiconductor device 100. For example, in the case where the sealing member 35 is a silicone gel, the amount of the low-molecular-weight siloxane, which is a liquid material that seeps out, is about 1 wt % with respect to the total amount of the silicone gel. Therefore, the insulating property of the semiconductor device 100 is not deteriorated.

In contrast to the semiconductor device 100 of the reference example, the semiconductor device 1 includes the projections 43a to 43e, so as to prevent the liquid material of the sealing member 35 from seeping out of the semiconductor device 1 as described below.

FIG. 5 is a diagram for describing the creeping of the sealing member in the semiconductor device according to the first embodiment.

In the semiconductor device 1, as in the case of FIG. 4, the liquid material contained in the sealing member 35 creeps up a component in the +Z direction and moves from a side wall 41 of the case 40 toward the through hole 42a along the rear surface of the lid 42. However, unlike the case of the semiconductor device 100, in the semiconductor device 1, the liquid material does not reach the through hole 42a unless the liquid material climbs over the projections 43a to 43e surrounding the through hole 42a over the plurality of circumferences in plan view. Therefore, the time until the liquid material reaches the through hole 42a is delayed.

As described above, it is possible to prevent the sealing member 35 from leaking to the outside of the semiconductor device 1. Even if the sealing member 35 leaks, the amount of leakage is reduced. Therefore, it is possible to prevent a decrease in the handleability of the semiconductor device 1.

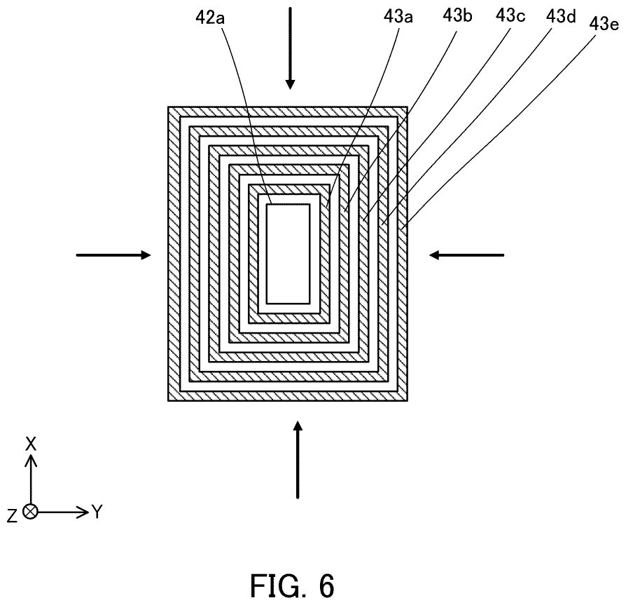

FIG. 6 illustrates an example of the arrangement positions of the projections with respect to creeping directions of the liquid material contained in the sealing member in the semiconductor device according to the first embodiment. In FIG. 6, creeping directions in which the liquid material creeps along the rear surface of the lid 42 after creeping up the four side walls 41 are indicated by arrows.

The projections 43a to 43e include portions extending in the directions perpendicular to the creeping directions of the liquid material contained in the sealing member 35. As illustrated in FIG. 6, the projections 43a to 43e include portions extending in the direction (±X direction) perpendicular to the creeping directions in the ±Y direction. In addition, the projections 43a to 43e include portions extending in the direction (±Y direction) perpendicular to the creeping directions in the ±X direction.

Since the projections 43a to 43e have the portions extending in the direction perpendicular to the creeping directions, the movement of the liquid material contained in the sealing member 35 is efficiently hindered, and the time until the liquid material reaches the through hole 42a is further delayed.

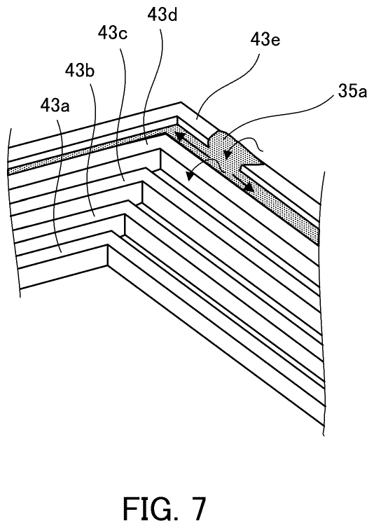

FIG. 7 is a perspective view illustrating a state in which the liquid material spreads in a region where the projections are provided. As illustrated in FIG. 7, grooves are formed between the projections 43a to 43e. Therefore, the liquid material 35a contained in the sealing member 35 does not simply move over the projections 43a to 43e in one direction toward the through hole 42a, but also moves in the extending directions of the grooves.

For example, as illustrated in FIG. 7, the liquid material 35a that has climbed over the projection 43e spreads in the groove between the projection 43e and the projection 43d, accumulates in the groove to some extent, and then climbs over the next projection 43d.

The grooves formed by providing the projections 43a to 43e over the plurality of circumferences as described above is able to further delay the arrival of the liquid material 35a at the through hole 42a.

### Second Embodiment

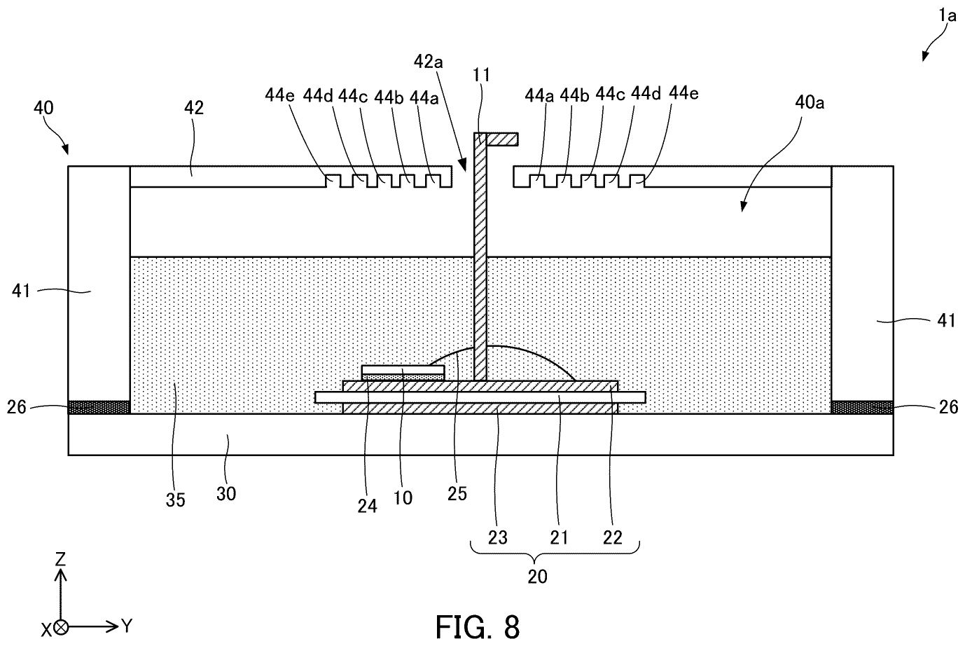

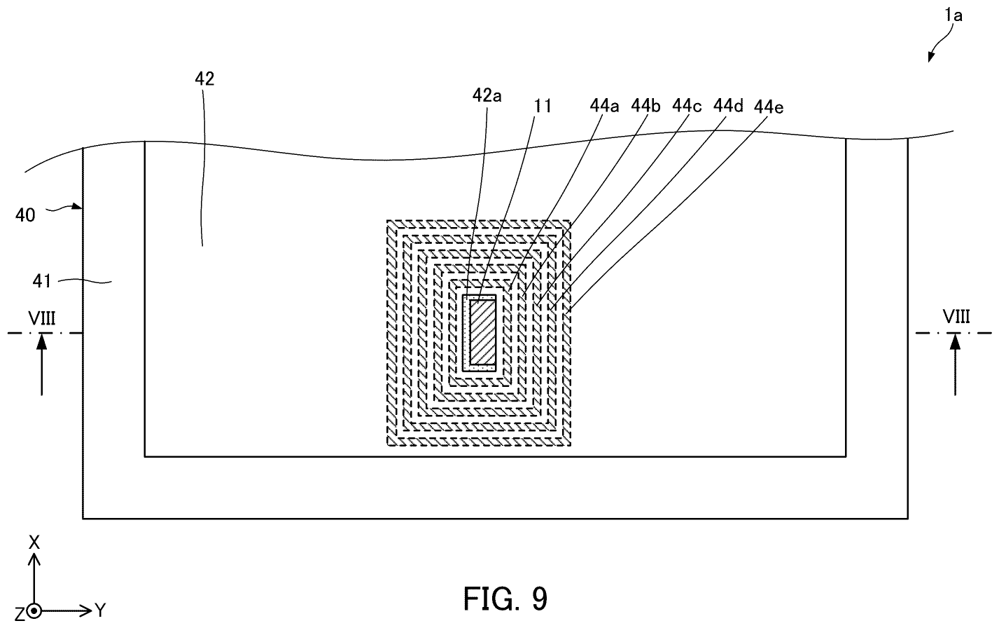

Next, a semiconductor device according to a second embodiment will be described with reference to FIGS. 8 and 9.

FIG. 8 is a side sectional view of the semiconductor device according to the second embodiment. FIG. 9 is a top view illustrating: of the semiconductor device according to the second embodiment. The sectional view of FIG. 8 is a view taken along the dash-dotted line VIII-VIII in FIG. 9. In FIG. 9, the positions of the grooves 44a to 44e formed in the inner surface of the lid 42 are indicated by broken lines. In FIGS. 8 and 9, the same elements as those illustrated in FIGS. 1 and 2 are denoted by the same reference numerals.

As illustrated in FIGS. 8 and 9, in the semiconductor device 1a of the second embodiment, grooves 44a to 44e are formed in the lid 42 of the case 40 instead of the projections 43a to 43e illustrated in FIGS. 1 and 2. The grooves 44a to 44e extend from the inner surface (rear surface) of the lid 42 toward the outer surface (front surface) of the lid 42 opposite to the inner surface.

The grooves 44a to 44e surround the through hole 42a over a plurality of circumferences to form circumferential patterns in plan view as illustrated in FIG. 9, and are provided in the inner surface of the lid 42 so as not to contact the sealing member 35 as illustrated in FIG. 1. In the example of FIG. 9, the grooves 44a to 44e are provided to surround the through hole 42a over the plurality of circumferences in a loop shape in plan view. More specifically, the grooves 44a to 44e are provided in the same number as the plurality of circumferences along the long side direction of the rectangular heat dissipation plate 30, and are also provided in the same number as the plurality of circumferences in the short side direction of the heat dissipation plate 30. The outer shape of each of the grooves 44a to 44e is rectangular in plan view.

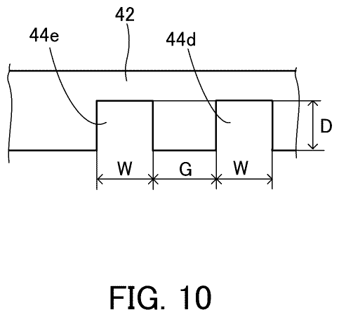

FIG. 10 is an enlarged view of grooves. The enlarge view of FIG. 10 illustrates the grooves 44d and 44e. The depths of the grooves 44d and 44e are denoted as D, the widths thereof are denoted as W, and the interval between the grooves 44d and 44e adjacent to each other in the inner peripheral direction or the outer peripheral direction is denoted as G. In the following description, with respect to the other grooves 44a to 44c, their depths are denoted as D, their widths are denoted as W, and the intervals between grooves adjacent to each other in the inner peripheral direction or the outer peripheral direction are denoted as G.

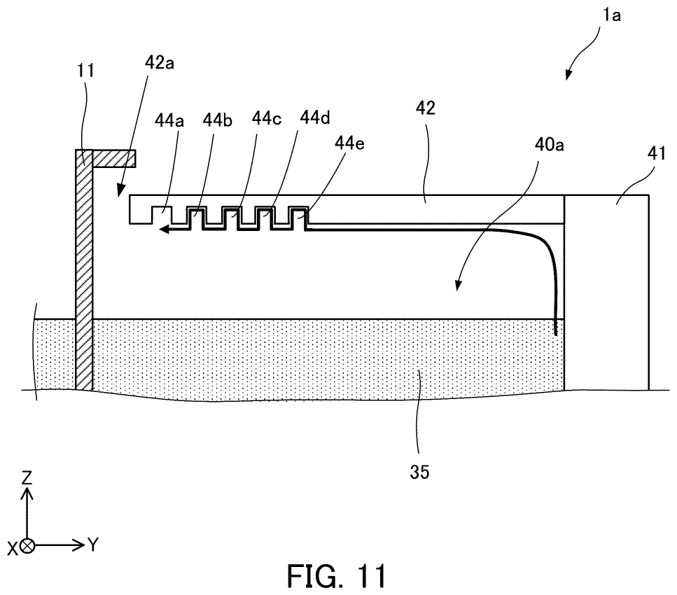

If the sizes of the grooves 44a to 44e is too large, the strength of the case 40 may decrease. However, as will be described later (see FIG. 11), the grooves 44a to 44c need to act to prevent the liquid material contained in the sealing member 35 from reaching the through hole 42a.

In view of the above, the depths D of the grooves 44a to 44e are preferably 1 mm or less, and the intervals G are preferably in the range of 0.5 mm to 1.5 mm, inclusive. The grooves 44a to 44e do not need to have the same depth D or the same width W. Further, the grooves 44a to 44e do not need to have the same intervals G therebetween. In the example of FIGS. 9 and 10, the grooves 44a to 44e extend vertically from the inner surface toward the outer surface of the lid 42, but are not limited thereto. The grooves 44a to 44e may be inclined within a range of about ±45° relative to the +Z direction from the inner surface of the lid 42.

Further, in the example of FIG. 10, the grooves 44a to 44e surround the through hole 42a over five circumferences in plan view, but are not limited thereto. The lid 42 may be formed with grooves that surround the through hole 42a over two to four circumferences or over six or more circumferences. The lid 42 and the grooves 44a to 44e are formed by integral molding.

In contrast to the semiconductor device 100 of the reference example illustrated in FIG. 4, the semiconductor device 1a of the second embodiment with the grooves 44a to 44e formed as described above is able to prevent the liquid material from seeping out of the semiconductor device 1a as described below.

FIG. 11 is a diagram for describing the creeping of the sealing member in the semiconductor device according to the second embodiment.

In the semiconductor device 1a, as in the case of FIG. 4, the liquid material contained in the sealing member 35 creeps up a component in the +Z direction and moves from a side wall 41 of the case 40 toward the through hole 42a along the rear surface of the lid 42. However, unlike the semiconductor device 100, in the semiconductor device 1a, the liquid material does not reach the through hole 42a unless the liquid material climbs over the grooves 44a to 44e surrounding the through hole 42a over the plurality of circumferences in plan view. Therefore, the time until the liquid material reaches the through hole 42a is delayed. From the above, as with the semiconductor device 1 of the first embodiment, the semiconductor device 1a of the second embodiment is able to prevent the sealing member 35 from leaking to the outside of the semiconductor device 1a.

Although not illustrated, the grooves 44a to 44e may include portions extending in directions perpendicular to directions in which the liquid material contained in the sealing member 35 creeps, as with the projections 43a to 43e. That is, the grooves 44a to 44e include portions extending in the direction (±X direction) perpendicular to the creeping directions in the ±Y direction. In addition, the grooves 44a to 44e include portions extending in the direction (±Y direction) perpendicular to the creeping directions in the ±X direction.

Since the grooves 44a to 44e have the portions extending in the directions perpendicular to the creeping directions, the movement of the liquid material contained in the sealing member 35 is efficiently hindered, and the time until the liquid material reaches the through hole 42a is further delayed.

In addition, the grooves 44a to 44e function in the same manner as the grooves between the projections 43a to 43e illustrated in FIG. 7. That is, the liquid material contained in the sealing member 35 does not simply move toward the through hole 42a over the grooves 44a to 44e in one direction, but also spreads in the extending directions of the grooves 44a to 44e.

For example, as illustrated in FIG. 11, the liquid material having creeped up the side wall 41 first moves along the inner surface of the lid 42 and spreads in the groove 44e. The liquid material accumulates in the groove 44e to some extent and then flows into the next groove 44d. The grooves 44a to 44e provided over the plurality of circumferences is able to further delay the arrival of the liquid material at the through hole 42a.

### (First Modification)

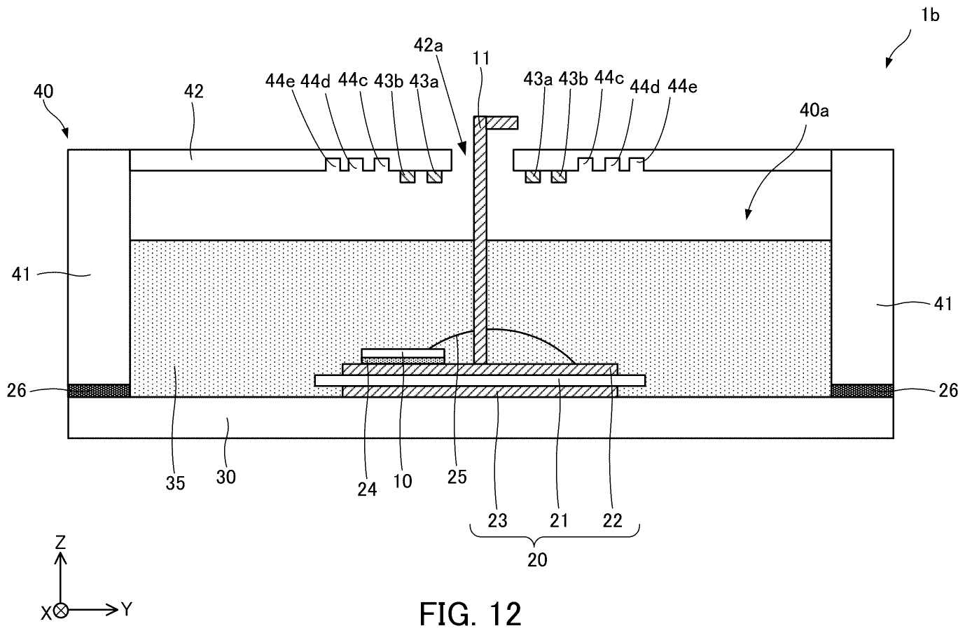

Next, a semiconductor device according to a first modification will be described with reference to FIG. 12.

FIG. 12 is a side sectional view of the semiconductor device according to the first modification.

In FIG. 12, the same elements as those illustrated in FIG. 1 or 8 are denoted by the same reference numerals.

The semiconductor device 1b of the first modification is an example in which both the projections 43a and 43b of the semiconductor device 1 of the first embodiment and the grooves 44c to of the semiconductor device 1a of the second embodiment are provided on the inner surface of the lid 42 of the case 40. In the example of FIG. 12, the projections 43a and 43b are formed on the inner peripheral side, and the grooves 44c to 44e are formed on the outer peripheral side. However, the positions of the projections and the grooves are not limited to the above example. For example, the following applications are conceivable.

The thickness of the lid 42 of the case 40 may vary depending on the location. In a thin portion where a groove of appropriate depth is not be able to be formed, a projection may be formed instead. On the other hand, in a thick portion where the tip of a projection would contact the surface of the sealing member 35, a groove may be formed instead. Alternatively, in the case where beams are formed on the inner surface of the lid 42 of the case 40, there may be a portion where a projection as formed in the semiconductor device 1 of the first embodiment would interfere with the beams. In such a portion, a groove may be formed instead.

The semiconductor device with both the projections and the grooves is also able to provide the same effect as the semiconductor device 1 of the first embodiment or the semiconductor device 1a of the second embodiment.

### (Second Modification)

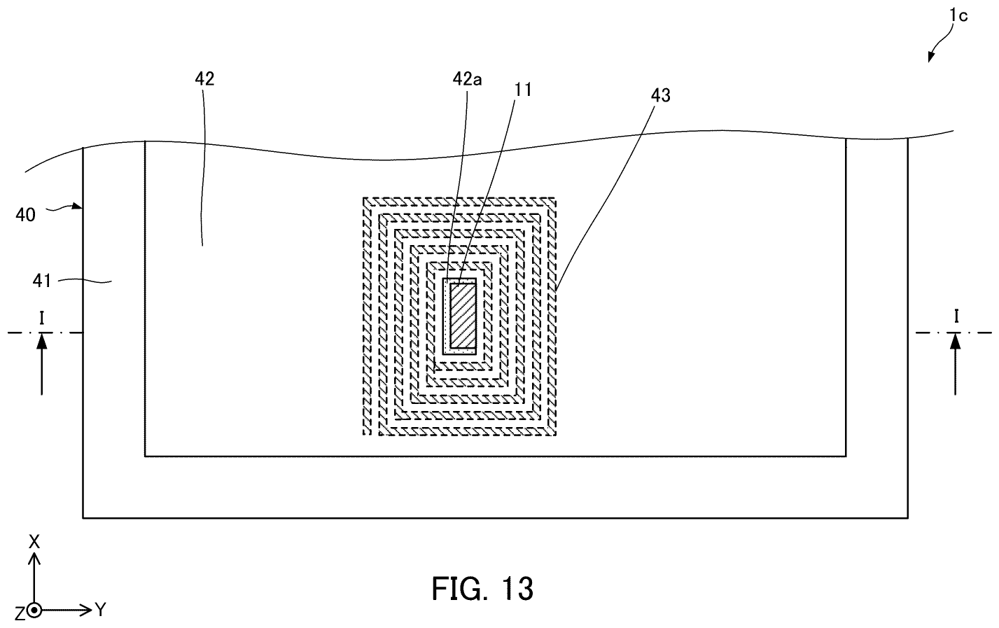

Next, a semiconductor device according to a second modification will be described with reference to FIG. 13.

FIG. 13 is a top view illustrating part of the semiconductor device according to the second modification. The cross section taken along the dash-dotted line I-I in FIG. 13 has the same configuration as the side sectional view of FIG. 1, and thus the illustration thereof is omitted. In FIG. 13, the same elements as those illustrated in FIG. 2 are denoted by the same reference numerals.

In each of the semiconductor devices 1 and 1a illustrated in FIGS. 1 and 8, the projections 43a to 43e (FIG. 2) or the grooves 44a to 44e (FIG. 9) are formed in a loop shape on the inner surface of the lid 42. However, the shapes of the projections and the grooves in plan view are not limited to the above shape.

As illustrated in FIG. 13, a projection 43 is provided in the semiconductor device 1c of the second modification so as to surround the through hole 42a in a spiral shape with a plurality of turns (or a plurality of circumference patterns) in plan view. Instead of the projection 43, a groove may be provided so as to surround the through hole 42a in a spiral shape with a plurality of turns in plan view.

The projection 43 (or groove) formed in this manner prevents the liquid material having seeped out of the sealing member 35 from reaching the through hole 42a. Thus, the projection 43 is able to provide substantially the same effect as the projections 43a to 43e or the grooves 44a to 44e described above.

### (Third Modification)

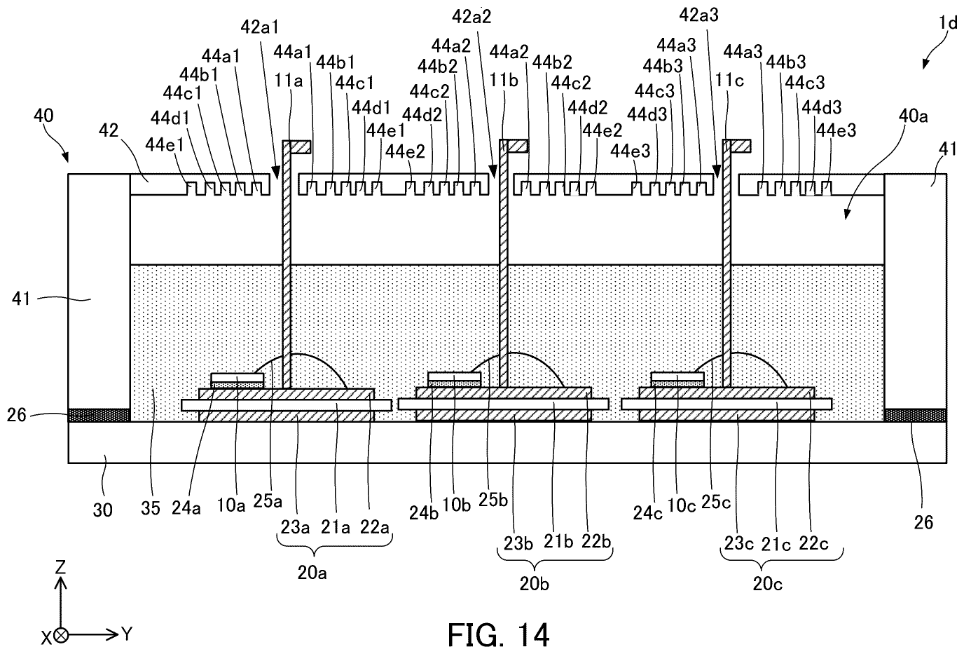

Next, a semiconductor device according to a third modification will be described with reference to FIG. 14.

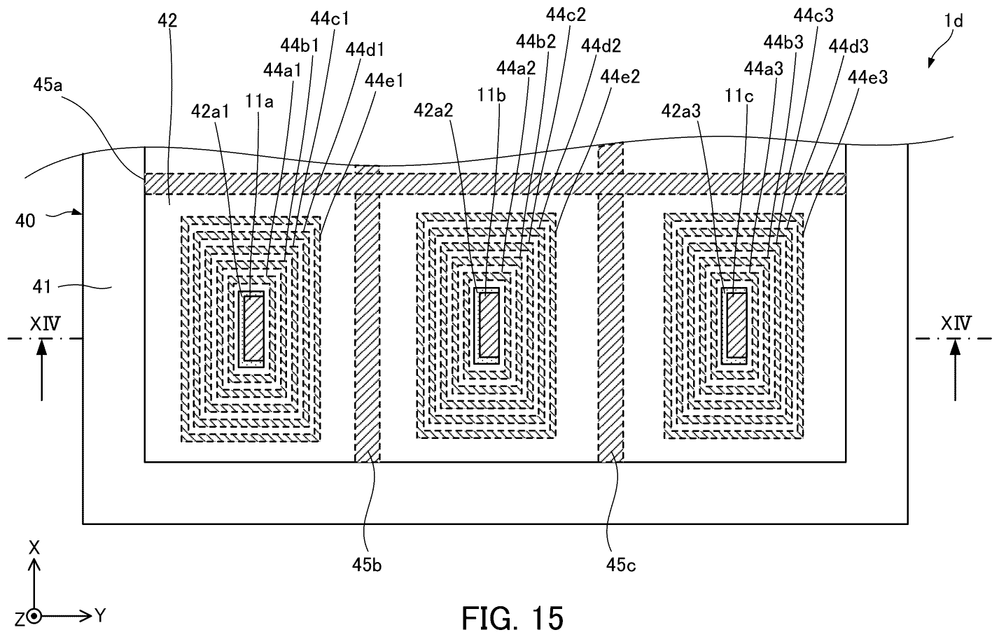

FIG. 14 is a side sectional view of a semiconductor device according to a third modification. FIG. 15 is top view illustrating part of the semiconductor device according to the third modification. The sectional view of FIG. 14 is a view taken along the dash-dotted line XIV-XIV in FIG. 15. In FIG. 15, the positions of grooves 44a1 to 44e1, 44a2 to 44e2, and 44a3 to 44e3 formed in the inner surface of the lid 42 are indicated by broken lines. In FIG. 14, the same elements as those illustrated in FIG. 1 or 8 are denoted by the same reference numerals.

In the semiconductor devices 1 and 1a illustrated in FIGS. 1 and 8, only one substrate 20 (on which the semiconductor chip 10 and the external connection terminals 11 are mounted) is provided in the Y direction, but the configuration is not limited thereto. In the semiconductor device 1d of the third modification, three substrates 20a to 20c are provided in the Y direction. The substrates 20a to 20c each correspond to the substrates 20 illustrated in FIGS. 1 and 8. External connection terminals 11a to 11c mounted on the substrates 20a to 20c each correspond to the external connection terminals 11 illustrated in FIGS. 1 and 8. Semiconductor chips 10a to 10c mounted on the substrates 20a to 20c each correspond to the semiconductor chips 10 illustrated in FIGS. 1 and 8. External connection terminals 11a to 11c mounted on the substrates 20a to 20c each correspond to the external connection terminals 11 illustrated in FIGS. 1 and 8.

The semiconductor chip 10a mounted on the substrate 20a is mechanically and electrically connected to the substrate 20a by a bonding wire 25a. The semiconductor chip 10b mounted on the substrate 20b is mechanically and electrically connected to the substrate 20b by a bonding wire 25b. The semiconductor chip 10c mounted on the substrate 20c is mechanically and electrically connected to the substrate 20c by a bonding wire 25c. For each of the semiconductor chips 10a to 10c, at least one of a switching element and a diode element is selected as needed, and their rear surfaces are directly bonded onto the predetermined circuit patterns 22a to 22c of the substrates 20a to 20c by bonding members 24a to 24c.

The external connection terminal 11a mounted on the substrate 20a is electrically connected to either the main electrode or the control electrode of the semiconductor chip 10a. The inner end portion of the external connection terminal 11a is bonded to the substrate 20a, and the outer end portion of the external connection terminal 11a extends outward from a through hole 42a1 provided in the lid 42 of the case 40. The external connection terminal 11b mounted on the substrate 20b is electrically connected to either the main electrode or the control electrode of the semiconductor chip 10b. The inner end portion of the external connection terminal 11b is bonded to the substrate 20b, and the outer end portion of the external connection terminal 11b extends outward from a through hole 42a2 provided in the lid 42 of the case 40. The external connection terminal 11c mounted on the substrate 20c is electrically connected to either the main electrode or the control electrode of the semiconductor chip 10c. The inner end portion of the external connection terminal 11c is bonded to the substrate 20c, and the outer end portion of the external connection terminal 11c extends outward from a through hole 42a3 provided in the lid 42 of the case 40. In the case where the semiconductor device 1d is a three-phase inverter device, the three external connection terminals 11a to 11c may serve as three-phase inverter output terminals of U, V, and W, for example.

The substrate 20a includes an insulating plate 21a, a circuit pattern 22a, and a metal plate 23a. The substrate 20b includes an insulating plate 21b, a circuit pattern 22b, and a metal plate 23b. The substrate 20c includes an insulating plate 21c, a circuit pattern 22c, and a metal plate 23c.

The three through holes 42a1 to 42a3 are formed in the lid 42 of the case 40 in the Y direction. The through holes 42a1 to 42a3 each correspond to the through holes 42a illustrated in FIGS. 1, 2, 8, and 9. In the example of FIGS. 14 and 15, the through hole 42a1 is used as a terminal hole through which the outer end portion of the external connection terminal 11a inserted. The through hole 42a2 is used as a terminal hole through which the outer end portion of the external connection terminal 11b is inserted. The through hole 42a3 is used as a terminal hole through which the outer end portion of the external connection terminal 11c is inserted.

As illustrated in FIG. 15, the grooves 44a1 to 44e1 are formed so as to surround the through hole 42a1 over a plurality of circumferences in plan view. As illustrated in FIG. 15, the grooves 44a2 to 44e2 are formed to surround the through hole 42a2 over a plurality of circumferences in plan view. As illustrated in FIG. 15, the grooves 44a3 to 44e3 are formed so as to surround the through hole 42a3 over a plurality of circumferences in plan view. The grooves 44a1 to 44e1, 44a2 to 44e2, and 44a3 to 44e3 correspond to the grooves 44a to 44e illustrated in FIGS. 8 and 9.

The grooves 44a1 to 44e1, 44a2 to 44e2, and 44a3 to 44e3 formed as described above are able to prevent the sealing member 35 from leaking through the through holes 42a1 to 42a3.

The semiconductor device 1d of the third modification may be modified to have projections like the projections 43a to 43e illustrated in FIGS. 1 and 2, instead of the grooves 44a1 to 44e1, 44a2 to 44e2, and 44a3 to 44e3.

In FIG. 15, the positions of beams 45a, 45b, and 45c out of a plurality of beams formed on the inner surface of the lid 42 are indicated by broken lines. The beam 45a extends in the Y direction on the inner surface of the lid 42. The both ends of the beam 45a are in contact with the side walls 41 at the points where the ends face the side walls 41 in the Y direction. The beam 45b extends in the X direction between the grooves 44a1 to 44e1 and the grooves 44a2 to 44e2 in plan view on the inner surface of the lid 42. One end of the beam 45b is in contact with the side wall 41 extending in the Y direction at the point where the end meets the side wall 41, and the other end of the beam 45b is in contact with the beam 45a. The beam 45c extends in the X direction between the grooves 44a2 to 44e2 and the grooves 44a3 to 44e3 in plan view on the inner surface of the lid 42. One end of the beam 45c is in contact with the side wall 41 extending in the Y direction at the point where the end meets the side wall 41, and the other end of the beam 45c is in contact with the beam 45a.

In order to distinguish from the projections 43a to 43e illustrated in FIGS. 1 and 2, for example, a plurality of projections, each having a height (length in the Z direction) of 2 mm or more, a width of 1 mm or more, and an interval of 1 mm or more from an adjacent projection, may be referred to as beams. For example, the heights of the beams 45a to 45c illustrated in FIG. 15 are in the range of 2 mm to 10 mm, inclusive, and the widths of the beams 45a to 45c is in the range of 1 mm to 5 mm, inclusive.

The beams 45a to 45c provided as described above are able to maintain the strength of the case 40 and to maintain the insulation distances between the external connection terminals 11a to 11c.

With the disclosed techniques, a semiconductor device with a through hole formed in the lid of the case is able to prevent a sealing member from leaking to the outside.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a semiconductor chip;
a substrate having the semiconductor chip mounted thereon;
a heat dissipation plate having a front surface on which the substrate is disposed;
a case having a side wall and a lid, the side wall being disposed on the front surface of the heat dissipation plate so as to surround a housing space together with the heat dissipation plate, the housing space accommodating the substrate therein, the lid being disposed on the side wall to cover the housing space; and
a sealing member filling the housing space to seal the substrate,
wherein the lid includes
a through hole, and
at least one projection or groove provided on an inner surface of the lid, configured to surround the through hole so as not to contact the sealing member such that the at least one projection or groove forms a plurality of circumferential patterns around the through hole in a plan view of the semiconductor device.

2. The semiconductor device according to claim 1, wherein
the sealing member contains a liquid material, and
the at least one projection or groove includes a portion extending in a direction perpendicular to a direction in which the liquid material creeps.

3. The semiconductor device according to claim 1, wherein the sealing member contains a silicone gel with a liquid low-molecular-weight siloxane.

4. The semiconductor device according to claim 1, wherein the at least one projection or groove includes a plurality of projections or grooves, each of which surrounds the through hole to form a loop shape in the plan view through the plurality of circumferential patterns.

5. The semiconductor device according to claim 1, wherein the at least one projection or groove surrounds the through hole to form a spiral shape in the plan view by the plurality of circumferential patterns.

6. The semiconductor device according to claim 1, wherein each of the at least one projection has a height of 2 mm or less in a thickness direction of the lid and a width in a range of 0.5 mm to 1.5 mm in a direction from the through hole to a peripheral edge of the lid, an interval between two adjacent ones of the plurality of circumferential patterns being in a range of 0.5 mm to 1.5 mm.

7. The semiconductor device according to claim 1, wherein the at least one groove has a depth of 1 mm or less in a thickness direction of the lid and a width in a range of 0.5 mm to 1.5 mm in a direction from the through hole to a peripheral edge of the lid, an interval between two adjacent ones of the plurality of circumferential patterns being in a range of 0.5 mm to 1.5 mm.

8. The semiconductor device according to claim 1, further comprising an external connection terminal including an inner end portion bonded to the substrate and an outer end portion extending outward through the through hole.

9. The semiconductor device according to claim 1, wherein
the heat dissipation plate is rectangular, and
the plurality of circumferential patterns formed by the at least one projection or groove includes a plurality of first portions extending in a long side direction of the heat dissipation plate, and a plurality of second portions extending in a short side direction of the heat dissipation plate, each of the plurality of first portions and the plurality of second portions being equal in number to the plurality of circumferential patterns.
